(19) United States
(12) Patent Application Publication
(10) Pub. No.: US 2018/0213608 A1
(43) Pub. Date: Jul. 26, 2018

(54) ELECTROSTATIC CHUCK WITH RADIO FREQUENCY ISOLATED HEATERS

(71) Applicant: Applied Materials, Inc., Santa Clara, CA (US)

(72) Inventors: David Benjaminson, Santa Clara, CA (US); Ken Schatz, Los Altos, CA (US); Dmitry Lubomirsky, Cupertino, CA (US)

(21) Appl. No.: 15/411,896

(22) Filed: Jan. 20, 2017

(51) Int. Cl. H05B 3/34; H01L 21/67; H01L 21/683

(52) U.S. Cl. CPC H05B 3/34; H01L 21/67103; H05B 2203/013; H05B 2203/017; H01L 21/6833

(57) ABSTRACT

A heater assembly for a substrate support assembly includes a flexible body. The heater assembly further includes one or more resistive heating elements disposed in the flexible body. The heater assembly further includes a first metal layer disposed on the top surface of the flexible body and extending at least partially onto an outer sidewall of the flexible body. The heater assembly further includes a second metal layer disposed on a bottom surface of the flexible body and extending at least partially onto the outer sidewall of the flexible body, wherein the second metal layer is coupled to the first metal layer at the outer sidewall of the flexible body such that the first metal layer and the second metal layer enclose, and form a continuous electrically conductive path around, the outer sidewall of the flexible body.

### TECHNICAL FIELD

Implementations described herein generally relate to semiconductor manufacturing and more particularly to a temperature controlled substrate support assembly and method of using the same.

### BACKGROUND

As the feature size of device patterns get smaller for integrated circuits, the critical dimension (CD) specifications of these features become a more important criterion for stable and repeatable device performance. Allowable CD variation across a substrate processed within a processing chamber is difficult to achieve due to chamber asymmetries such as chamber and substrate temperature, flow conductance, and radio frequency (RF) fields.

In processes utilizing an electrostatic chuck, temperature control across the surface of the substrate is even more challenging due to RF interference. For example, the electrostatic chuck includes a resistance heater assembly that is exposed to RF signals from an RF generator. The resistance heater assembly becomes a path for the RF signals, preventing even distribution of the RF signal over the surface of the electrostatic chuck and affecting performance of the resistance heater assembly. The heater assembly may also be exposed to chemicals during the etching process, which deteriorates the heater assembly.

### SUMMARY

Implementations described herein provide a substrate support assembly with a heater assembly that is protected from an RF signal.

In one implementation, a heater assembly for a substrate support assembly includes a flexible body and one or more main resistive heating elements disposed in the flexible body. The heater assembly further includes a plurality of additional resistive heating elements disposed in the flexible body. The heater assembly further includes a first metal layer disposed on a top surface of the flexible body and extending at least partially onto an outer sidewall of the flexible body. The heater assembly further includes a second metal layer disposed on a bottom surface of the flexible body and extending at least partially onto the outer sidewall of the flexible body, wherein the second metal layer is coupled to the first metal layer at the outer sidewall of the flexible body such that the first metal layer and the second metal layer enclose, and form a continuous electrically conductive path around, the outer sidewall of the flexible body.

In one implementation, a substrate support assembly includes a metal cooling plate, a heater assembly coupled to the metal cooling plate and an electrostatic chuck disposed on the heater assembly. The heater assembly includes a body including an upper surface, a lower surface and an outer sidewall, wherein the lower surface of the body is disposed on the metal cooling plate. The body further includes one or more resistive heating elements disposed in the body. The body further includes a metal layer disposed on the upper surface of the body, wherein the metal layer extends along the outer sidewall of the body to the metal cooling plate and is coupled to the metal cooling plate, and wherein the metal layer and metal cooling plate together enclose the heater assembly and form a continuous electrically conductive path around the outer sidewall of the heater assembly. The electrostatic chuck includes a ceramic body and an electrode disposed in the ceramic body.

In one implementation, a method includes providing a heater assembly including a body having an upper surface, a lower surface and an outer sidewall, wherein the heater assembly further includes and a plurality of heating elements disposed in the flexible body. The method further includes disposing a first metal layer on the upper surface of the heater assembly, wherein the first metal layer extends at least partially onto an outer sidewall of the body. The method further includes disposing a second metal layer on the lower surface of the heater assembly, wherein the second metal layer extends at least partially onto the outer sidewall of the body. The method further includes coupling the first metal layer and the second metal layer such that the first metal layer and second metal layer enclose, and form a continuous electrically conductive path around, the outer sidewall of the body.

### BRIEF DESCRIPTION OF THE DRAWINGS

So that the manner in which the above recited features of implementations of the present invention can be understood in detail, a more particular description, briefly summarized above, may be had by reference to the implementations, some of which are illustrated in the appended drawings. It is to be noted, however, that the appended drawings illustrate only some embodiments of this invention and are not to be considered limiting of its scope.

FIG. 1 is a cross-sectional schematic side view of a processing chamber having one embodiment of a substrate support assembly;

FIG. 2 is a partial cross-sectional schematic side view detailing portions of the substrate support assembly;

FIGS. 3A-3D are partial schematic side views illustrating various locations for spatially tunable heaters and main resistive heaters within the substrate support assembly;

FIG. 4 is a cross-sectional view taken along a section line A-A of FIG. 2;

FIG. 5 is a graphical depiction for a wiring schema for the spatially tunable heaters and main resistive heaters;

FIG. 6 is a graphical depiction for an alternate wiring schema for the spatially tunable heaters and main resistive heaters;

FIG. 7 is an illustration of disposing the metal layers onto the body, according to embodiments.

FIG. 8 is an illustration of a heater assembly, according to one embodiment.

FIG. 9 is an illustration of a heater assembly, according to another embodiment.

FIG. 10 is an illustration of a heater assembly, according to a further embodiment.

FIG. 11 is an illustration of a metal layer, according to an embodiment.

FIG. 12 is an illustration of a heater assembly, according to an embodiment.

FIG. 13 is a flow diagram of one embodiment of a method for processing a heater assembly.

FIG. 14 is a flow diagram of another embodiment of a method for processing a heater assembly.

To facilitate understanding, identical reference numerals have been used, where possible, to designate identical elements that are common to the figures. It is contemplated that elements disclosed in one implementation may be beneficially used in other implementations without specific recitation.

### DETAILED DESCRIPTION

Implementations described herein provide a substrate support assembly that includes a heater assembly that is enclosed in metal. The metal encloses and provides a continuous electrically conductive path around the heater assembly. By enclosing the heater assembly in metal in embodiments, the heater assembly is shielded from any RF signals. The RF signals would ordinarily introduce some amount of RF influence on the operation of resistive heaters in the heater assembly. The amount of influence by the RF signals on the resistive heaters may be greater near a periphery of the heater assembly than near a center of the heater assembly. Such interference may cause the resistive heaters to output heat a temperature that is greater than and/or lower than a target temperature, and may thus introduce uncertainty into a manufacturing process. By encasing the heater assembly in a metal layer or film, such RF influence by the RF signals may be reduced or eliminated. The metal layer or film around the heater assembly may act as a faraday cage, and may provide the continuous electrically conductive path around the heater assembly. Thus, when an RF signal reaches the heater assembly, that RF signal will flow around the heater assembly rather than through any portion of the heater assembly. Causing the RF signal to flow around the heater assembly may improve the accuracy of the temperatures output by the heater assembly. Additionally, this may causing the RF signal to flow around the heater assembly may also cause a more even distribution of RF power to be delivered to a substrate supported by the substrate support assembly.

Moreover, the heater assembly may be composed of a flexible material such as polyimide that may be susceptible to erosion and/or corrosion caused by a corrosive environment. By enclosing the heater assembly in metal, the heater assembly may be protected from the corrosive environment (e.g., from chemistry and etching chemicals within a processing chamber). Methods for enclosing and providing a continuous electrically conductive path around the heater assembly are also described herein.

In embodiments, a substrate support assembly includes multiple heating zones. Each heating zone may be heated by a heating element located in that heating zone. A substrate support assembly may include anywhere from two heating zones to hundreds of heating zones (e.g., 150 heating zones or 200 heating zones in some embodiments).

Although the substrate support assembly is described below in an etch processing chamber, the substrate support assembly may be utilized in other types of processing chambers, such as physical vapor deposition chambers, chemical vapor deposition chambers, ion implantation chambers, and other processing chambers where enclosing and providing a continuous electrically conductive path around a heater assembly is desirable. It is also contemplated that the enclosed heater assemblies may also be utilized to control the temperature of other surfaces, including those not used for semiconductor processing.

In one or more embodiments, the substrate support assembly allows for the correction of critical dimension (CD) variation at the edge of a supported substrate during processes such as etching, deposition, implantation and the like based on adjusting the substrate temperature to compensate for chamber non-uniformities such as temperature, flow conductance, electrical fields (e.g., RF fields), plasma chemistry and the like. Additionally, some embodiments provide a substrate support assembly able to control the temperature uniformity across the substrate to less than about ±0.3 degrees Celsius.

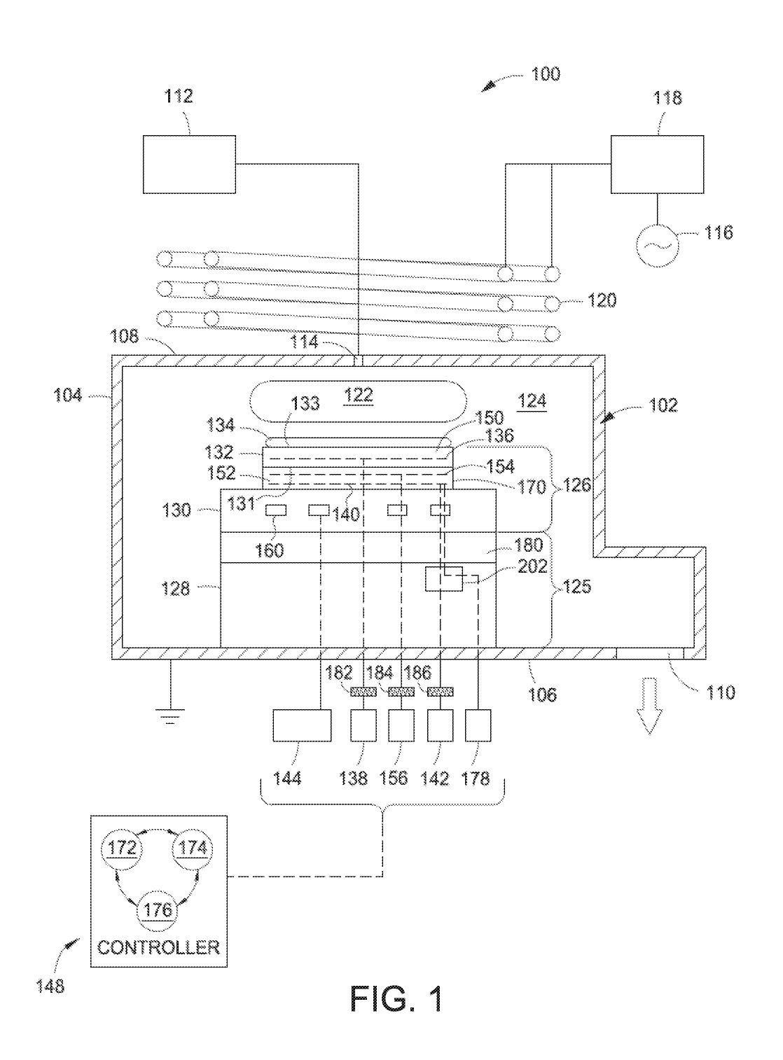

FIG. 1 is a cross-sectional schematic view of an exemplary etch processing chamber 100 having a substrate support assembly 126. As discussed above, the substrate support assembly 126 may be utilized in other processing chambers, such as plasma treatment chambers, annealing chambers, physical vapor deposition chambers, chemical vapor deposition chambers, ion implantation chambers, and so on. Additionally, the substrate support assembly 126 may be used for other systems where the ability to control a temperature profile of a surface or workpiece, such as a substrate, is desirable. Independent and local control of the temperature across many discrete regions across a surface beneficially enables azimuthal tuning of the temperature profile, center to edge tuning of the temperature profile, and reduction of local temperature asperities, such as hot and cool spots.

The processing chamber 100 includes a grounded chamber body 102 in one embodiment. The chamber body 102 includes walls 104, a bottom 106 and a lid 108 which enclose an internal volume 124. The substrate support assembly 126 is disposed in the internal volume 124 and supports a substrate 134 during processing.

The walls 104 of the processing chamber 100 may include an opening (not shown) through which the substrate 134 may be robotically transferred into and out of the internal volume 124. A pumping port 110 is formed in one of the walls 104 or the bottom 106 of the chamber body 102 and is fluidly connected to a pumping system (not shown). The pumping system may maintain a vacuum environment within the internal volume 124 of the processing chamber 100, and may remove processing byproducts from the processing chamber.

A gas panel 112 may provide process gases and/or other gases to the internal volume 124 of the processing chamber 100 through one or more inlet ports 114 formed in the lid 108 and/or walls 104 of the chamber body 102. The process gases provided by the gas panel 112 may be energized within the internal volume 124 to form a plasma 122 utilized to process the substrate 134 disposed on the substrate support assembly 126. The process gases may be energized by RF power inductively coupled to the process gases from a plasma applicator 120 positioned outside the chamber body 102. In the embodiment depicted in FIG. 1, the plasma applicator 120 is a pair of coaxial coils coupled through a matching circuit 118 to an RF power source 116.

A controller 148 is coupled to the processing chamber 100 to control operation of the processing chamber 100 and processing of the substrate 134. The controller 148 may be a general-purpose data processing system that can be used in an industrial setting for controlling various subprocessors and subcontrollers. Generally, the controller 148 includes a central processing unit (CPU) 172 in communication with memory 174 and input/output (I/O) circuitry 176, among other common components. Software commands executed by the CPU of the controller 148 may cause the processing chamber to, for example, introduce an etchant gas mixture (i.e., processing gas) into the internal volume 124, form the plasma 122 from the processing gas by application of RF power from the plasma applicator 120, and etch a layer of material on the substrate 134.

The substrate support assembly 126 generally includes at least a substrate support 132. The substrate support 132 may be a vacuum chuck, an electrostatic chuck, a susceptor, or other workpiece support surface. In the embodiment of FIG. 1, the substrate support 132 is an electrostatic chuck and will be described hereinafter as the electrostatic chuck 132. The substrate support assembly 126 may additionally include a heater assembly 170 that includes main resistive heating elements 154 (also referred to as main resistive heaters) and a plurality of additional resistive heating elements referred to herein as spatially tunable heating elements 140 (also referred to as spatially tunable heaters). In embodiments the heater assembly 170 is enclosed in a metal layer, which may be composed of aluminum, copper, titanium, tungsten, stainless steel, a combination or alloy of one or more of these metals, or another metal. The metal layer that encloses the heater assembly 170 may cause an RF field to flow around the heater assembly 170, and may additionally protect a body of the heater assembly 170 from corrosion and erosion.

The substrate support assembly 126 may also include a cooling base 130. The cooling base 130 may alternately be separate from the substrate support assembly 126. The substrate support assembly 126 may be removably coupled to a support pedestal 125. The support pedestal 125, which may include a pedestal base 128 and a facility plate 180, is mounted to the chamber body 102. The substrate support assembly 126 may be periodically removed from the support pedestal 125 to allow for refurbishment of one or more components of the substrate support assembly 126.

The facility plate 180 is configured to accommodate one or more driving mechanisms configured to raise and lower a multiple lifting pins. Additionally, the facility plate 180 is configured to accommodate fluid connections from the electrostatic chuck 132 and the cooling base 130. The facility plate 180 is also configured to accommodate electrical connections from the electrostatic chuck 132 and the heater assembly 170. The myriad of connections may run externally or internally of the substrate support assembly 126, and the facility plate 180 may provide an interface for the connections to a respective terminus.

The electrostatic chuck 132 has a mounting surface 131 and a workpiece surface 133 opposite the mounting surface 131. The electrostatic chuck 132 generally includes a chucking electrode 136 embedded in a dielectric body 150. The chucking electrode 136 may be configured as a mono polar or bipolar electrode, or other suitable arrangement. The chucking electrode 136 may be coupled through a radio frequency (RF) filter 182 to a chucking power source 138 which provides an RF or direct current (DC) power to electrostatically secure the substrate 134 to the upper surface of the dielectric body 150. The RF filter 182 prevents RF power utilized to form a plasma 122 within the processing chamber 100 from damaging electrical equipment or presenting an electrical hazard outside the chamber. The dielectric body 150 may be fabricated from a ceramic material, such as AlN or Al₂O₃. Alternately, the dielectric body 150 may be fabricated from a polymer, such as polyimide, polyetheretherketone, polyaryletherketone and the like.

A workpiece surface 133 of the electrostatic chuck 132 may include gas passages (not shown) for providing backside heat transfer gas to an interstitial space defined between the substrate 134 and the workpiece surface 133 of the electrostatic chuck 132. The electrostatic chuck 132 may also include lift pin holes for accommodating lift pins (both not shown) for elevating the substrate 134 above the workpiece surface 133 of the electrostatic chuck 132 to facilitate robotic transfer into and out of the processing chamber 100.

The temperature controlled cooling base 130 is coupled to a heat transfer fluid source 144. The heat transfer fluid source 144 provides a heat transfer fluid, such as a liquid, gas or combination thereof, which is circulated through one or more conduits 160 disposed in the cooling base 130. The fluid flowing through neighboring conduits 160 may be isolated to enable local control of the heat transfer between the electrostatic chuck 132 and different regions of the cooling base 130, which assists in controlling the lateral temperature profile of the substrate 134.

A fluid distributor (not shown) may be fluidly coupled between an outlet of the heat transfer fluid source 144 and the temperature controlled cooling base 130. The fluid distributor operates to control an amount of heat transfer fluid provided to the conduits 160. The fluid distributor may be disposed outside of the processing chamber 100, within the substrate support assembly 126, within the pedestal base 128, or at another suitable location.

The heater assembly 170 may include one or more main resistive heaters 154 and/or a plurality of spatially tunable heaters 140 embedded in a body 152. The body 152 may additionally include a plurality of temperature sensors. Each of the plurality of temperature sensors may be used to measure a temperature at a region of the heater assembly and/or of a region of an electrostatic chuck associated with a region of the heater assembly. In one embodiment, the body 152 is a flexible polyimide or other flexibly polymer. In another embodiment, the body is a ceramic such as AlN or Al2O3. In one embodiment, the body has a disc shape.

The main resistive heaters 154 may be provided to elevate the temperature of the substrate support assembly 126 to a temperature for conducting chamber processes. The spatially tunable heaters 140 are complimentary to the main resistive heaters 154 and are configured to adjust the localized temperature of the electrostatic chuck 132 in a plurality of discrete locations within one or more of a plurality of laterally separated heating zones defined by the main resistive heaters 154. The spatially tunable heaters 140 provide localized adjustments to the temperature profile of the substrate 134 placed on the substrate support assembly 126. The main resistive heaters 154 operate on a globalized macro scale while the spatially tunable heaters 140 operate on a localized micro scale.

The main resistive heaters 154 may be coupled through an RF filter 184 to a main heater power source 156. The main heater power source 156 may provide 900 watts or more power to the main resistive heaters 154. The controller 148 may control the operation of the main heater power source 156, which is generally set to heat the substrate 134 to about a predefined temperature. In one embodiment, the main resistive heaters 154 include laterally separated heating zones, wherein the controller 148 enables one zone of the main resistive heaters 154 to be preferentially heated relative to the main resistive heaters 154 located in one or more of the other zones. For example, the main resistive heaters 154 may be arranged concentrically in a plurality of separated heating zones.

The spatially tunable heaters 140 may be coupled through an RF filter 186 to a tuning heater power source 142. The tuning heater power source 142 may provide 10 watts or less power to the spatially tunable heaters 140. In one embodiment, the power supplied by the tuning heater power source 142 is an order of magnitude less than the power supplied by the power source 156 of the main resistive heaters. The spatially tunable heaters 140 may additionally be coupled to a tuning heater controller 202. The tuning heater controller 202 may be located within or external to the substrate support assembly 126. The tuning heater controller 202 may manage the power provided from the tuning heater power source 142 to individual tunable heaters 140 or to groups of spatially tunable heaters 140 in order to control the heat generated locally at each spatially tunable heater 140 distributed laterally across the substrate support assembly 126. The tuning heater controller 202 is configured to independently control an output of one of the spatially tunable heaters 140 relative to another of the spatially tunable heaters 140. An optical converter 178 may be coupled to the tuning heater controller 202 and to the controller 148 to decouple the controller 148 from influence of RF energy within the processing chamber 100.

The electrostatic chuck 132 and/or heater assembly 170 may include a plurality of temperature sensors (not shown) for providing temperature feedback information. The temperature feedback information may be sent to the controller 148 for determining an operability of the main resistive heaters 154, for controlling the power applied by the main heater power source 156 to the main resistive heaters 154, for controlling the operations of the cooling base 130, and/or for controlling the power applied by the tuning heater power source 142 to the spatially tunable heaters 140. Alternatively, or additionally, the temperature feedback information may be provided to the heater controller 202 for determining the operability of the spatially tunable heaters 140 and/or for controlling the power applied to the spatially tunable heaters 140. Each temperature sensor may be located proximate to one of the spatially tunable heaters and may be used to determine an operability of the nearby spatially tunable heater. In one embodiment, each temperature sensor is a resistance temperature detector (RTD). As used herein, the term proximate may mean separated by less than 2 mm. The material separating the spatially tunable heaters 140 from the temperature sensors may be polyimide, Al₂O₃, AlN, or another dielectric material.

The temperature of the surface for the substrate 134 in the processing chamber 100 may be influenced by the evacuation of the process gasses by the pump, by the slit valve door, by the plasma 122, by an RF signal or RF field and/or by other factors. The cooling base 130, the one or more main resistive heaters 154, and the spatially tunable heaters 140 all help to control the surface temperature of the substrate 134.

In a two zone configuration of the main resistive heaters 154, the main resistive heaters 154 may be used to heat the substrate 134 to a temperature suitable for processing with a variation of about +/−10 degrees Celsius from one zone to another. In a four zone configuration for the main resistive heaters 154, the main resistive heaters 154 may be used to heat the substrate 134 to a temperature suitable for processing with a variation of about +/−1.5 degrees Celsius within a particular zone. Each zone may vary from adjacent zones from about 0 degrees Celsius to about 20 degrees Celsius depending on process conditions and parameters. However, the advantage of minimizing variations in the critical dimensions across a substrate has reduced the acceptable variation in a determined process temperature of the surface of the substrate surface. A half a degree variation of the surface temperature for the substrate 134 may result in as much as a nanometer difference in the formation of structures therein. The spatially tunable heaters 140 improve the temperature profile of the surface of the substrate 134 produced by the main resistive heaters 154 by reducing variations in the temperature profile to about +/−0.3 degrees Celsius. The temperature profile may be made uniform or to vary precisely in a predetermined manner across regions of the substrate 134 through the use of the spatially tunable heaters 140.

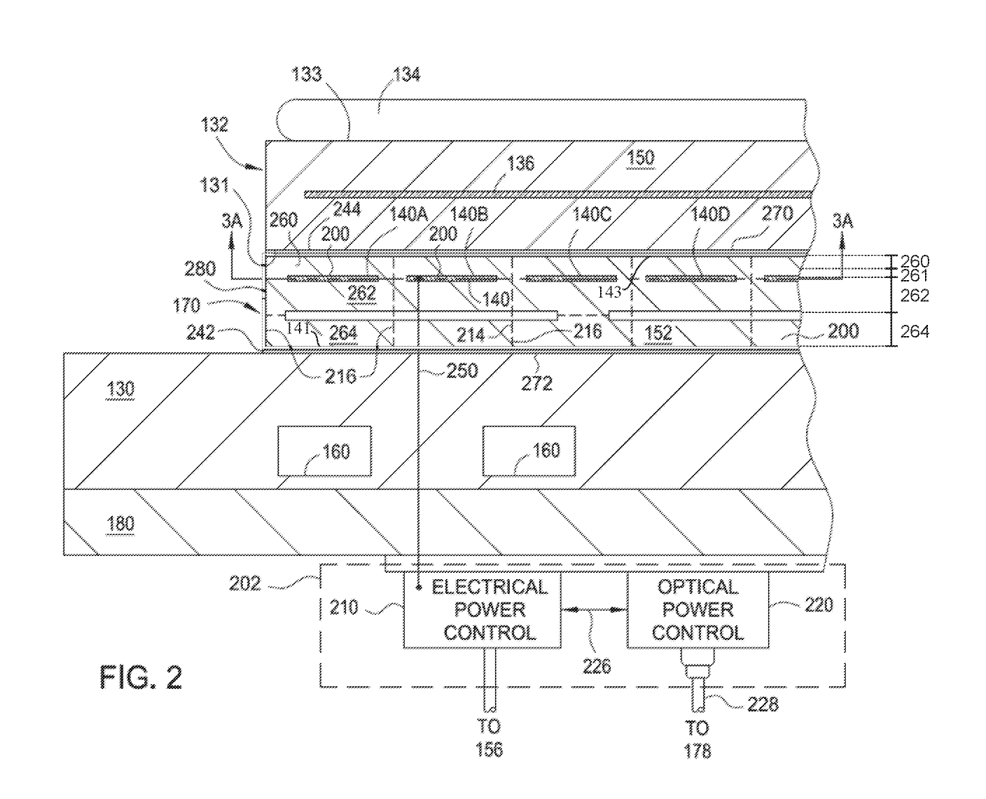

FIG. 2 is a partial cross-sectional schematic view illustrating portions of the substrate support assembly 126. Included in FIG. 2 are portions of the electrostatic chuck 132, the cooling base 130, the heater assembly 170 and the facility plate 180.

The body 152 of the heater assembly 170 may be fabricated from a polymer such as a polyimide. Accordingly, the body 152 may be a flexible body in embodiments. The body 152 may generally be cylindrical, but may also be formed in other geometrical shapes. The body 152 has an upper surface 270 and a lower surface 272. The upper surface 270 faces the electrostatic chuck 132, while the lower surface 272 faces the cooling base 130. In one embodiment, the upper surface of the cooling base 130 may include a recessed portion and the body 152 may be disposed in the recessed portion of the cooling base 130.

The body 152 of the heater assembly 170 may be formed from two or more dielectric layers (shown in FIG. 2 as four dielectric layers 260, 261, 262, 264) and heating the layers 260, 261, 262, 264 under pressure to form a single body 152. For example, the body 152 may be formed from polyimide layers 260, 261, 262, 264, which separate the main resistive heaters 154 and the spatially tunable heaters 140. The polyimide layers 260, 261, 262, 264 may be heated under pressure to form the single body 152 of the heater assembly 170. The spatially tunable heaters 140 may be placed in, on or between the first, second, third and/or fourth layers 260, 261, 262, 264 prior to forming the body 152. Additionally, the main resistive heaters 154 may be placed in, on or between on the first, second, third and/or fourth layers 260, 261, 262, 264 prior to assembly, with at least one of the layers 260, 261, 262, 264 separating and electrically insulating the main resistive heaters 154 and the spatially tunable heaters 140. In this manner, the spatially tunable heaters 140, and the main resistive heaters 154 become an integral part of the heater assembly 170. In one embodiment, the heater assembly 170 may include temperature sensors. Alternatively, the heater assembly 170 may not include any temperature sensors.

A metal layer 141 may be disposed on the bottom surface of the body 152. The metal layer 141 may extend past and/or onto the sidewall 280 of the body 152. Additionally, a metal layer 143 may be disposed on the top surface of the body 152 and may extend past and/or onto the sidewall 280 of the body 152. Metal layers 141 and 143 may be coupled to enclose the body 152. In one embodiment, the metal layers 141 and 143 may be coupled by welding the metal layer 141 to the metal layer 143 (e.g., by welding an area near or at the outer diameter of metal layer 141 to an area near or at the outer diameter of metal layer 143 as illustrated in FIG. 10). The weld may be a continuous weld without gaps between the metal layers 141 and 143. The continuous weld may be around the diameters of metal layers 141 and 143 to enclose the body 152. The continuous weld may provide a continuous electrically conductive path for RF signals along the sidewall 280 of the body 152. The welding operation may be performed using any operation capable of forming the continuous weld around the diameters of metal layers 141 and 143. In one embodiment, the weld may be an electron beam weld (also referred to as an “EB weld” herein) in which a beam of high-velocity electrons is applied to metal layers 141 and 143 while the metals layers 141 and 143 are in contact. In another embodiment, the weld may be a tungsten inert gas weld (also referred to as a “TIG weld” herein) that uses a non-consumable tungsten electrode to produce the weld. The metal layers 141 and 143 may be formed from Aluminum (Al), Silver (Ag), Copper (Cu), Gold (Au), Zinc (Zn), tungsten, stainless steel, an alloy or combination of any of these metals, or another suitable material. The metal layers 141 and 143 may have a thickness from 0.001″ to 0.125″. In one embodiment, the metal layers may have a thickness from 0.002″ to 0.030″.

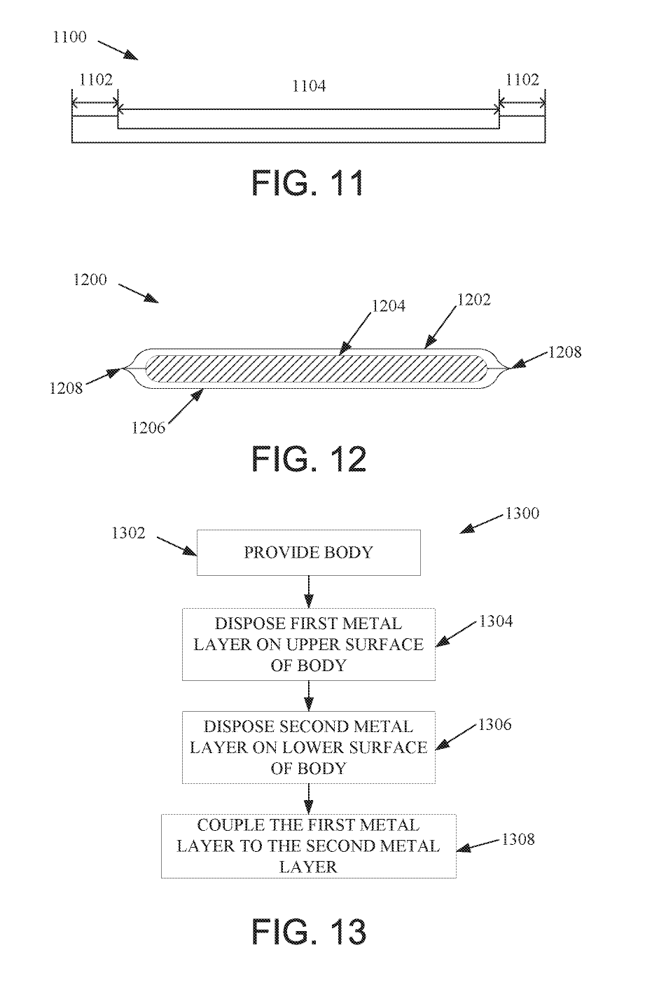

In one embodiment, metal layer 141 may be coupled to metal layer 143 by a metal ring (not shown), as illustrated in FIGS. 11 and 12.

In one embodiment, the heater assembly 170 may include metal layer 143 on the top surface of the body 152 but may not include metal layer 141 on the bottom surface of the body 152. In the embodiment that lacks metal layer 141, the metal layer 143 may be coupled to the cooling base 130 to enclose the body 152. The metal layer 143 may be coupled to the cooling plate 130 by a continuous weld. The welding operation may be performed using any process capable of forming the continuous weld, such as EB welding, TIG welding, or another suitable process.

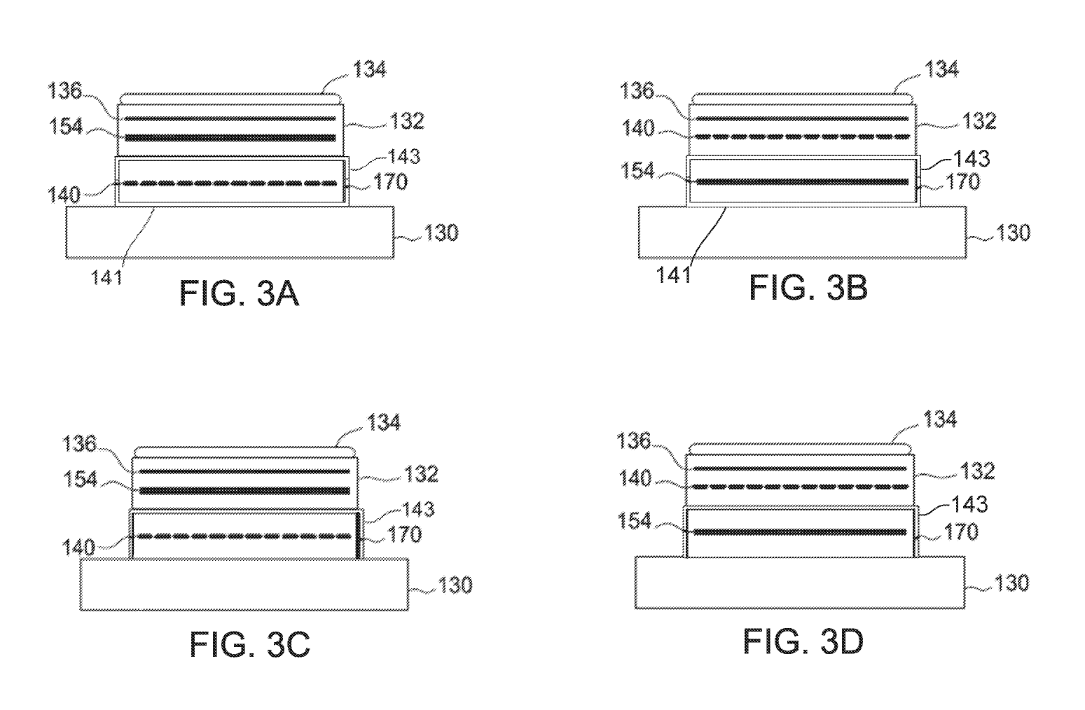

Alternate configurations for locations of the main resistive heaters 154 and the spatially tunable heaters 140 may place one or more of the main resistive heaters 154 and/or spatially tunable heaters 140 in or under the electrostatic chuck 132. FIGS. 3A-3D are partial schematic views of the substrate support assembly 126 detailing various locations for the spatially tunable heaters 140 and the main resistive heaters 154.

In the embodiment depicted in FIG. 3A, the heater assembly 170 for the substrate support assembly 126 includes the spatially tunable heaters 140 and metal layers 141 and 143 while the main resistive heaters 154 are disposed in the electrostatic chuck 132, for example, below the chucking electrode 136. Alternatively, the spatially tunable heaters 140 may be disposed in the electrostatic chuck 132 while the main resistive heaters 154 are disposed in the heater assembly 170.

In the embodiment depicted in FIG. 3B, the heater assembly 170 for the substrate support assembly 126 includes metal layers 141 and 143 and has the main resistive heaters 154 disposed therein. The spatially tunable heaters 140 are disposed in the electrostatic chuck 132, for example, below the chucking electrode 136.

In the embodiment depicted in FIG. 3C, the heater assembly 170 for the substrate support assembly 126 includes the spatially tunable heaters 140 and metal layer 143 while the main resistive heaters 154 are disposed in the electrostatic chuck 132, for example, below the chucking electrode 136. The metal layer 143 may be coupled to the cooling base 130. Alternatively, the spatially tunable heaters 140 may be disposed in the electrostatic chuck 132 while the main resistive heaters 154 are disposed in the heater assembly 170. Alternatively, the heater assembly 170 may include the main resistive heaters 154 and the electrostatic chuck may not include any heaters or the heater assembly 170 may include the spatially tunable heaters 154 and the electrostatic chuck may not include any heaters.

In the embodiment depicted in FIG. 3D, the heater assembly 170 for the substrate support assembly 126 includes metal layer 143 and has the main resistive heaters 154 disposed therein. The metal layer 143 may be coupled to the cooling base 130. The spatially tunable heaters 140 are disposed in the electrostatic chuck 132, for example, below the chucking electrode 136.

It is contemplated that the spatially tunable heaters 140, the main resistive heaters 154 may be arranged in other orientations. For example, the substrate support assembly 126 may have the plurality of spatially tunable heaters 140 for heating the substrate 134, but may lack the main resistive heaters 154. Alternatively, the substrate support assembly 126 may have the main resistive heaters 154 but may lack the spatially tunable heaters 140. In one embodiment, the spatially tunable heaters 140 and the main resistive heaters 154 are disposed directly under each other within substrate support assembly 126. The spatially tunable heaters 140 may provide fine tune control for the temperature profile of the substrate 134 supported by the substrate support assembly 126.

In each of the examples shown in FIGS. 3A-3D, one or more conductive planes may be formed in the electrostatic chuck 132 and/or heater assembly 170 to be used as a common ground for multiple spatially tunable heaters 140. In one embodiment, a first conductive plane is used as a common ground for the spatially tunable heaters and is connected to the spatially tunable heaters by vias. In one embodiment, a second conductive plane is used as a common ground for the temperature sensors and is connected to the temperature sensors by vias. The conductive planes may each be metal layers disposed within the electrostatic chuck or conductive planes disposed within the heater assembly 170.

Returning back to FIG. 2, the spatially tunable heaters 140 may be formed or disposed in the body 152 of the heater assembly 170. Alternatively, the spatially tunable heaters 140 may be formed or disposed in electrostatic chuck 132. The spatially tunable heaters 140 may be formed by plating, ink jet printing, screen printing, physical vapor deposition, stamping, wire mesh, pattern polyimide flex circuit, or by other suitable manner Vias may be formed in the heater assembly 170 or electrostatic chuck 132 for providing connections from the spatially tunable heaters 140 to an exterior surface of the heater assembly 170 or electrostatic chuck 132. Alternatively, or additionally, a metal layer (not shown) may be formed in the heater assembly 170 or in the electrostatic chuck 132. Vias may be formed in the heater assembly 170 or electrostatic chuck 132 for providing connection from the spatially tunable heaters 140 to the metal layer. Additional vias may be formed that connect the metal layer to an exterior surface of the heater assembly 170 or electrostatic chuck 132.

In one example, the body 150 of the electrostatic chuck 132 may have vias formed therein between the spatially tunable heaters 140 and the mounting surface 131 of the body 150. In another example, the body 152 of the heater assembly 170 may have vias formed therein between the spatially tunable heaters 140 and a surface of the body 152 adjacent the cooling base 130. In another example, the body 150 of the electrostatic chuck 132 may have vias formed therein between the spatially tunable heaters 140 and the metal layer, and between the metal layer and the mounting surface 131 of the body 140. In this manner fabrication of the substrate support assembly 126 is simplified.

In one embodiment, the spatially tunable heaters 140 are disposed within the heater assembly 170 while forming the heater assembly 170. In another embodiment, the spatially tunable heaters 140 are directly disposed on the mounting surface 131 of the electrostatic chuck 132. For example, the spatially tunable heaters 140 may be in a sheet form which can be adhered to the mounting surface 131 of the electrostatic chuck 132, or the spatially tunable heaters 140 may be deposited by other techniques. For example, the spatially tunable heaters 140 can be deposited on the mounting surface 131 by physical vapor deposition, chemical vapor deposition, screen printing or other suitable methods. The main resistive heaters 154 can be in the electrostatic chuck 132 or heater assembly 170 as shown above.

The main resistive heaters 154 may be formed or disposed in the body 152 of the heater assembly 170 or electrostatic chuck 132. The main resistive heaters 154 may be formed by plating, ink jet printing, screen printing, physical vapor deposition, stamping, wire mesh or other suitable manner In this manner fabrication of the substrate support assembly 126 is simplified. In one embodiment, main resistive heaters 154 are disposed within the heater assembly 170 while forming the heater assembly 170. In another embodiment, main resistive heaters 154 are directly disposed on the mounting surface 131 of the electrostatic chuck 132. For example, main resistive heaters 154 may be in a sheet form which can be adhered to the mounting surface 131 of the electrostatic chuck 132, or main resistive heaters 154 may be deposited by other techniques. For example, main resistive heaters 154 can be deposited on the mounting surface 131 by physical vapor deposition, chemical vapor deposition, screen printing or other suitable methods. The spatially tunable heaters 140 can be in the electrostatic chuck 132 or heater assembly 170 as shown above.

In some embodiments, the main resistive heaters 154 are fabricated similar to the spatially tunable heaters 140. In embodiments where the main resistive heaters 154 are fabricated similar to the spatially tunable heaters 140, the main resistive heaters may optionally be utilized without benefit of additional spatially tunable heaters 140. In other words, the main resistive heaters 154 of the substrate support assembly 126 may themselves be spatially tunable, that is, segmented in to a plurality of discreet resistive heating elements. Segmenting the main resistive heaters 154 in the form of small resistive heaters allows local control of hot and cold spots on the surface of the substrate 134. An additional layer of spatially tunable heaters 140 is optional, depending on the level of temperature control to be implemented.

The heater assembly 170 may be coupled to the mounting surface 131 of the electrostatic chuck 132 utilizing a bonding agent 244. The bonding agent 244 may be an adhesive, such as an acrylic-based adhesive, an epoxy, a silicone based adhesive, a neoprene-based adhesive or other suitable adhesive. In one embodiment, the bonding agent 244 is an epoxy. The bonding agent 244 may have a coefficient of thermal conductivity selected in a range from 0.01 to 200 W/mK and, in one exemplary embodiment, in a range from 0.1 to 10 W/mK. The adhesive materials comprising the bonding agent 244 may additionally include at least one thermally conductive ceramic filler, e.g., aluminum oxide (Al₂O₃), aluminum nitride (AlN), and titanium diboride (TiB₂), and the like.

In one embodiment, the heater assembly 170 is coupled to the cooling base 130 utilizing a bonding agent 242. The bonding agent 242 may be similar to the bonding agent 244 and may be an adhesive, such as an acrylic-based adhesive, an epoxy, a neoprene-based adhesive, a silicone adhesive, or other suitable adhesive. In one embodiment, the bonding agent 242 is an epoxy. The bonding agent 242 may have a coefficient of thermal conductivity selected in a range from 0.01 to 200 W/mK and, in one exemplary embodiment, in a range from 0.1 to 10 W/mK. The adhesive materials comprising the bonding agent 242 may additionally include at least one thermally conductive ceramic filler, e.g., aluminum oxide (Al₂O₃), aluminum nitride (AlN), and titanium diboride (TiB₂), and the like. In one embodiment, the bonding agent may be a dielectric. In one embodiment, the bonding agent may be non-conductive at direct current.

The bonding agents 244, 242 may be removed when refurbishing one or more of the electrostatic chuck 132, the cooling base 130 and the heater assembly 170. In other embodiments, the heater assembly 170 is removably coupled to the electrostatic chuck 132 and to the cooling base 130 utilizing fasteners or clamps (not shown).

The heater assembly 170 may include a plurality of spatially tunable heaters 140, illustratively shown as spatially tunable heaters 140A, 140B, 140C, 140D, and so on. The spatially tunable heaters 140 are generally an enclosed volume within the heater assembly 170 in which a plurality of resistive heaters effectuate heat transfer between the heater assembly 170 and electrostatic chuck 132. Each spatially tunable heater 140 may be laterally arranged across the heater assembly 170, and defines a cell 200 within the heater assembly 170 for locally providing additional heat to a region of the heater assembly 170 (and a portion of the main resistive heater 154) aligned with that cell 200. The number of spatially tunable heaters 140 formed in the heater assembly 170 may vary, and it is contemplated that there is at least an order of magnitude more spatially tunable heaters 140 (and cells 200) greater than the number of the main resistive heaters 154. In one embodiment in which the heater assembly 170 has four main resistive heaters 154, there may be greater than 40 spatially tunable heaters 140. However, it is contemplated that there may be about 200, about 400 or even more spatially tunable heaters 140 in a given embodiment of a substrate support assembly 126 configured for use with a 300 mm substrate. Exemplary distribution of the spatially tunable heaters 140 are described further below with reference to FIGS. 3A-3D.

The heater assembly 170 may further include metal layers 141 and 143. The metal layers 141 and 143 maybe coupled to enclose the body 152 of the heater assembly 170. In one embodiment, the metal layers 141 and 143 may be coupled by welding an area near the outer diameter of metal layer 141 to an area near the outer diameter of metal layer 143 as illustrated in FIG. 10. The weld may be a continuous weld around the diameters of metal layers 141 and 143 to enclose the body 152. The metal layers 141 and 143 may be formed from Al, Ag, Cu, Au, Zn, or another suitable material. In one embodiment, the metal layers 141, 143 have a thickness that is at least the skin depth of the metal used for the metal layers 141, 143 at an RF frequency that is used. In one embodiment, the metal layers 141, 143 have a thickness that is 2-50 times (e.g., 3 times, 4 times, 5 times, 10 times, etc.) the skin depth of the metal used for the metal layers 141, 143 at the RF frequencies that are used. Skin depth is a function of the electrical conductivity and permeability of the material and of an RF frequency. For aluminum at an RF frequency of 13.56 MHz (which may be used in embodiments), the skin depth is about 0.001″. Accordingly, the metal layers 141 and 143 may have a thickness from 0.001″ to 0.040″. In one embodiment, the metal layers have a thickness of about 0.002-0.03″. In another embodiment, metal layer 141 may be coupled to metal layer 143 by a metal ring, as illustrated in FIGS. 11 and 12.

The cells 200 may be formed through one or more layers 260, 262, 264 comprising the body 152 of the heater assembly 170. In one embodiment, the cells are open to the lower and upper surface 270, 272 of the body 152. The cells may include sidewalls 214. The sidewalls 214 may be comprised of a material (or gap) acting as a thermal choke 216. The thermal chokes 216 may be formed in the upper surface 270 of the body 152. The thermal chokes 216 separate and reduce conduction between adjacent cells 200. By individually and independently controlling the power provided to each spatially tunable heater 140, and consequently the heat transfer through cell 200, a pixel by pixel approach to temperature control can be realized which enables specific points of the substrate 134 to be heated or cooled, enabling a truly addressable lateral temperature profile tuning and control of the surface of the substrate 134.

An additional thermal choke 216 may be formed between the radially outermost cells 200 and a laterally outermost sidewall 280 of the body 152. This outermost thermal choke 216 located between the outermost cells 200 and the laterally outermost sidewall 280 of the body 152 minimizes heat transfer between the cells 200 adjacent to the laterally outermost sidewall 280 and the internal volume 124 of the processing chamber 100. The minimization of heat transfer between the outermost cells 200 and the internal volume 124 allows for more precise temperature control closer to the edge of the substrate support assembly 126, and as a result, better temperature control to the outside diameter edge of the substrate 134.

Each spatially tunable heater 140 may be independently coupled to the tuning heater controller 202. In one embodiment, the tuning heater controller 202 may be disposed in the substrate support assembly 126. The tuning heater controller 202 may regulate the temperature of the spatially tunable heaters 140 in the heater assembly 170 at each cell 200 relative to the other cells 200. Alternatively, the tuning heater controller 202 regulate the temperature of a group of spatially tunable heaters 140 in the heater assembly 170 across a group of cells 200 relative to the another group of cells 200. The tuning heater controller 202 may toggle the on/off state and/or control a duty cycle for individual spatially tunable heaters 140. Alternately, the tuning heater controller 202 may control the amount of power delivered to the individual spatially tunable heaters 140. For example, the tuning heater controller 202 may provide one or more spatially tunable heaters 140 ten watts of power, other spatially tunable heaters 140 nine watts of power, and still other spatially tunable heaters 140 one watt of power.

In one embodiment, each cell 200 may be thermally isolated from the neighboring cells 200, for example, using a thermal choke 216, which enables more precise temperature control. In another embodiment, each cell 200 may be thermally joined to an adjacent cell creating an analogue (i.e., smooth or blended) temperature profile along an upper surface 270 of the heater assembly 170. For example, a metal layer, such as aluminum foil, may be used as a thermal spreader between the main resistive heaters 154 and the spatially tunable heaters 140.

The use of independently controllable spatially tunable heaters 140 to smooth out or correct the temperature profile generated by the main resistive heaters 154 enable control of the local temperature uniformity across the substrate to very small tolerances, and enables precise process and CD control when processing the substrate 134. Additionally, the small size and high density of the spatially tunable heaters 140 relative to the main resistive heaters 154 enables temperature control at specific locations on the substrate support assembly 126, without substantially affecting the temperature of neighboring areas. This allows local hot and cool spots to be compensated for without introducing skewing or other temperature asymmetries. The substrate support assembly 126, having a plurality of spatially tunable heaters 140, has an ability to control the temperature uniformity of a substrate 134 processed thereon to less than about ±0.3 degrees Celsius.

Another benefit of some embodiments of the substrate support assembly 126 is the ability to prevent RF power from traveling through control circuitry. For example, the tuning heater controller 202 may include an electrical power circuit 210 and an optical power controller 220. The electrical power circuit 210 is coupled to the spatially tunable heaters 140. Each spatially tunable heater 140 has a pair of power leads (connectors 250) which are connected to the electrical power circuit 210. In an exemplary heater assembly 170 having fifty spatially tunable heaters 140, 60 hot and 1 common power lead (connectors 250) may be used for controlling the spatially tunable heaters 140. RF energy may be supplied into the processing chamber 100 for forming the plasma, and may couple to the power leads. Filters, such as the RF filters 182, 184, 186 shown in FIG. 1, may be used to protect electrical equipment, such as the main heater power source 156, from the RF energy. By terminating the power leads (connectors 250) at the electrical power circuit 210, and utilizing the optical power controller 220 to each spatially tunable heater 140, a single RF filter 184 may be used between the electrical power circuit 210 and the power source 156. Instead of each heater having a dedicated RF Filter, the spatially tunable heaters are able to use one RF filter which significantly reduces the number of RF filters that are used. The space for dedicated RF filters is very limited, and the number of heaters utilized within the substrate support assembly is also limited. The number of main heater zones is not limited, and implementing spatially tunable heaters becomes possible. The use of the electrical power circuit 210 with the optical power controller 220 allows for more heaters, and consequently, superior lateral temperature control.

The electrical power circuit 210 may switch or cycle power to the plurality of connectors 250. The electrical power circuit 210 provides power to each of the connectors 250 to activate one or more spatially tunable heaters 140. Although the electrical power source ultimately supplies power to the plurality of spatially tunable heaters 140, the electrical power circuit 210 has a single power source, i.e. the tuning heater power source 142, and uses the single filter 184. Advantageously, the space and expense for additional filters are mitigated, while enabling use of many heaters and heater zones.

The optical power controller 220 may be coupled to the electrical power controller 210 by a fiber optic interface 226, such as a fiber optic cable, to control the power supplied to the connectors 250 and the spatially tunable heaters 140. The optical power controller 220 may be coupled to the optical converter 178 through an optical wave guide 228. The optical converter 178 is coupled to the controller 148 for providing signals controlling the function of the spatially tunable heaters 140. The fiber optic interface 226 and optical wave guide 228 are not subject to electromagnetic interference or radio frequency (RF) energy. An RF filter to protect the controller 148 from RF energy transmission from the tuning heater controller 202 is unnecessary, which allows more space in the substrate support assembly 126 for routing other utilities.

The optical controller 220 may send commands, or instructions, to the electrical power circuit 210 for regulating each spatially tunable heater 140 or groups/regions of spatially tunable heaters 140. Each spatially tunable heater 140 may be activated using a combination of a positive lead and a negative lead, i.e., the connectors 250, attached to the electrical power circuit 210. Power may flow from electrical power circuit 210 over the positive lead to the spatially tunable heater 140 and return over the negative lead back to the electrical power circuit 210. In one embodiment, the negative leads are shared amongst the spatially tunable heaters 140. The spatially tunable heaters 140 may each have an individual dedicated positive lead while sharing a common negative lead. In this arrangement, the number of connectors 250 from the electrical power circuit 210 to the plurality of spatially tunable heaters 140 is one more than the number of spatially tunable heaters 140. For example, if the substrate support assembly 126 has one hundred (100) spatially tunable heaters 140, there would be 100 positive leads and 1 negative lead for a total of 101 connectors 250 between the spatially tunable heaters 140 and the electrical power circuit 210. In another embodiment, each spatially tunable heater 140 has a separate negative lead connecting the spatially tunable heater 140 to the electrical power circuit 210. In this arrangement, the number of connectors 250 from the electrical power circuit 210 to the spatially tunable heaters 140 is twice the number of spatially tunable heaters 140. For example, if the substrate support assembly 126 has one hundred (100) spatially tunable heaters 140, there would be 100 positive leads and 100 negative leads for a total of 200 connectors 250 between the spatially tunable heaters 140 and the electrical power circuit 210.

The optical power controller 220 may be programmed and calibrated by measuring the temperature at each spatially tunable heater 140. The optical controller 220 may control the temperature by adjusting the power parameters for individual spatially tunable heaters 140. In one embodiment, the temperature may be regulated with incremental power increases to the spatially tunable heaters 140. For example, a temperature rise may be obtained with a percentage increase, for example 9% increase, in the power supplied to the spatially tunable heater 140. In another embodiment, the temperature may be regulated by cycling the spatially tunable heater 140 on and off. In yet another embodiment, the temperature may be regulated by a combination of cycling and incrementally adjusting the power to each spatially tunable heater 140. A temperature map may be obtained using this method. The temperature map may correlate the CD or temperature to the power distribution curve for each spatially tunable heater 140. The spatially tunable heater 140 may be used to generate a temperature profile on the substrate based on a program regulating power settings for the individual spatially tunable heaters 140. The logic can be placed directly in the optical controller 220 or in an externally connected controller, such as the controller 148.

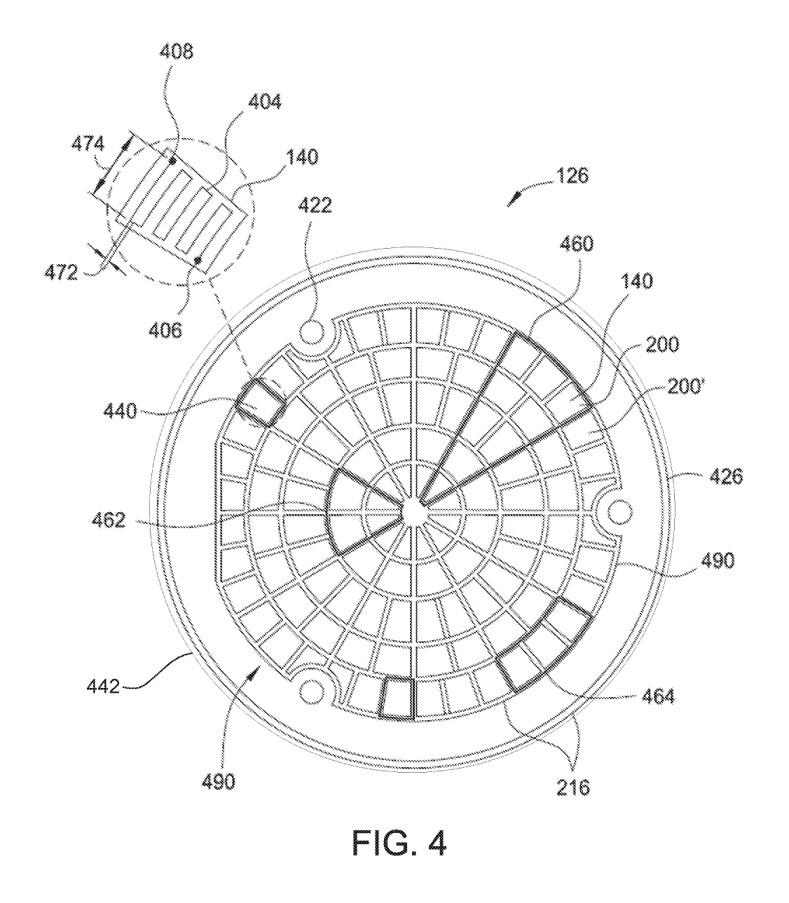

The arrangement of the spatially tunable heaters 140 will now be discussed with reference to FIG. 4. FIG. 4 is a cross-sectional view of FIG. 2 along a section line A-A, according to one embodiment.

Referring now to FIG. 4, the plurality of spatially tunable heaters 140 are disposed along the plane of the cross section line A-A through the body 152 of the heater assembly 170. The thermal choke 216 is disposed between each neighboring cell 200, each cell 200 is associated with at least one of the spatially tunable heaters 140. Additionally, the thermal choke 216 is disposed along an outer surface 426 of the substrate support assembly 126. Around the outer surface 426 is metal layer 442 that includes metal layers 141 and 143. The metal layer 442 includes a continuous weld between metal layers 141 and 143 to enclose the heater assembly 170. The number of cells 200 shown is for illustration only, and any number of embodiments may have substantially more (or less) cells 200. The number of spatially tunable heaters 140 may be at least an order of magnitude greater than the number of main resistive heaters 154. The number of spatially tunable heaters 140 located across the substrate support assembly 126 may be in excess of several hundred in some embodiments.

Each spatially tunable heater 140 has a resistor 404 ending in terminals 406, 408. As current enters one terminal, such as the terminal labeled 406, and exists the other terminal, such as the terminal labeled 408, the current travels across the wire of the resistor 404 and generates heat. The spatially tunable heater 140 may have a design power density to provide the appropriate temperature rise along the outer surface 426 of the substrate support assembly 126. The amount of heat released by the resistor 404 is proportional to the square of the current passing therethrough. The power design density may be between about 1 watt/cell to about 100 watt/cell, such as 10 watt/cell.

The resistor 404 may be formed from a film of nichrome, rhenium, tungsten, platinum, tantalum or other suitable materials. The resistor 404 may have an electrical resistivity (p). A low p indicates a material that readily allows the movement of an electric charge across the resistor 404. The resistance (R) is dependent on the p times the length (l) over the cross sectional area (A) of the wire, or simply R=ρ·l/A. Platinum has a ρ of about 1.06×10⁻⁷ (Ω·m) at 20° C. Tungsten has a p of about 6.60×10⁻⁸(Ω·m) at 20° C. Nichrome has a p of about 1.1×10⁻⁸ to about 1.5×10⁻⁸(Ω·m) at 20° C. Of the three aforementioned materials, the resistor 404 comprised of nichrome allows the electrical charge to move more readily, and generate more heat. However, the electrical properties for tungsten may differentiate the material as a resistive heater in certain temperature ranges.

The resistor 404 may have a film thickness (not shown) and a wire thickness 472 configured to efficiently provide heat when a current is passed along the resistor 404. An increase in the wire thickness 472 for the resistor 404 may result in a decrease in the resistance R of the resistor 404. The wire thickness 472 may range from about 0.05 mm to about 0.5 mm for a tungsten wire and about 0.5 mm to about 1 mm for a nichrome wire.

Recalling the formula R=ρ·l/A, it can be seen that the material, length of wire, and the wire thickness may be selected for the resistor 404 to control cost, power consumption, and the heat generated by each spatially tunable heater 140. In one embodiment, a resistor 404 is comprised of tungsten having a wire thickness 472 of about 0.08 mm and a resistance of about 90 Ohms at 10 watts of power.

The spatially tunable heaters 140 may be configured in a pattern 490 to efficiently generate a heat profile along the surface of the substrate support assembly 126. The pattern 490 may be symmetric about a midpoint while providing clearance in and around holes 422 for lift pins or other mechanical, fluid or electrical connections. Each spatially tunable heater 140 may be controlled by the tuning heater controller 202. The tuning heater controller 202 may turn on a single spatially tunable heater 140 defining a heater 440; or a plurality of spatially tunable heaters 140 grouped to define an inner wedge 462, a perimeter group 464, a pie shaped area 460, or other geometric configuration, including non-contiguous configurations. In this manner, temperature can be precisely controlled at independent locations along the surface of the substrate support assembly 126, such independent locations not limited to a concentric ring such as known in the art. Although the pattern shown is comprised of smaller units, the pattern may alternatively have larger and/or smaller units, extend to the edge, or have other forms.

In an alternative embodiment, the spatially tunable heaters 140 are arranged in the form of a grid, defining an array of temperature control cells 200 also arranged in the grid pattern. The grid pattern of spatially tunable heaters 140 may be an X/Y grid comprised of rows and columns. Alternatively, the grid pattern of spatially tunable heaters 140 may have some other uniformly packed form, such as a hexagon close pack. It should be appreciated, as discussed above, that the spatially tunable heaters 140 may be activated in groups or singularly.

In another embodiment, the plurality of spatially tunable heaters 140 may be arranged in a polar array in the body 152. Optionally, one or more of thermal chokes 216 may be disposed between the spatially tunable heaters 140. The polar array pattern of the spatially tunable heaters 140 defines the neighboring cells 200, which are also be arranged in a polar array. Optionally, thermal chokes 216 may be utilized to isolate adjacent cells 200 from neighboring cells 200.

In another embodiment, a plurality of spatially tunable heaters 140 are arranged in the body 152 in concentric channels. The concentric channel pattern of the spatially tunable heaters 140 may be optionally separated by thermal chokes 216. It is contemplated that the spatially tunable heaters 140 and cells 200 may be arranged in other orientations.

The number and density of the spatially tunable heaters 140 contribute to the ability for controlling the temperature uniformity across the substrate to very small tolerances which enables precise process and CD control when processing the substrate 134. Additionally, individual control of one spatially tunable heater 140 relative to another spatially tunable heater 140 enables temperature control at specific locations in the substrate support assembly 126 without substantially affecting the temperature of neighboring areas, which enables local hot and cool spots to be compensated for without introducing skewing or other temperature asymmetries. The spatially tunable heaters 140 may have an individual temperature range between about 0.0 degrees Celsius and about 10.0 degrees Celsius with the ability to control the temperature rise in increments of about 0.1 degrees Celsius. In one embodiment, the plurality of spatially tunable heaters 140 in the substrate support assembly 126 in conjunction with the main resistive heaters 154 have an ability to control the temperature uniformity of a substrate 134 processed thereon to less than about ±0.3 degrees Celsius. The spatially tunable heaters 140 allow both lateral and azimuthal tuning of the lateral temperature profile of the substrate 134 processed on the substrate support assembly 126.

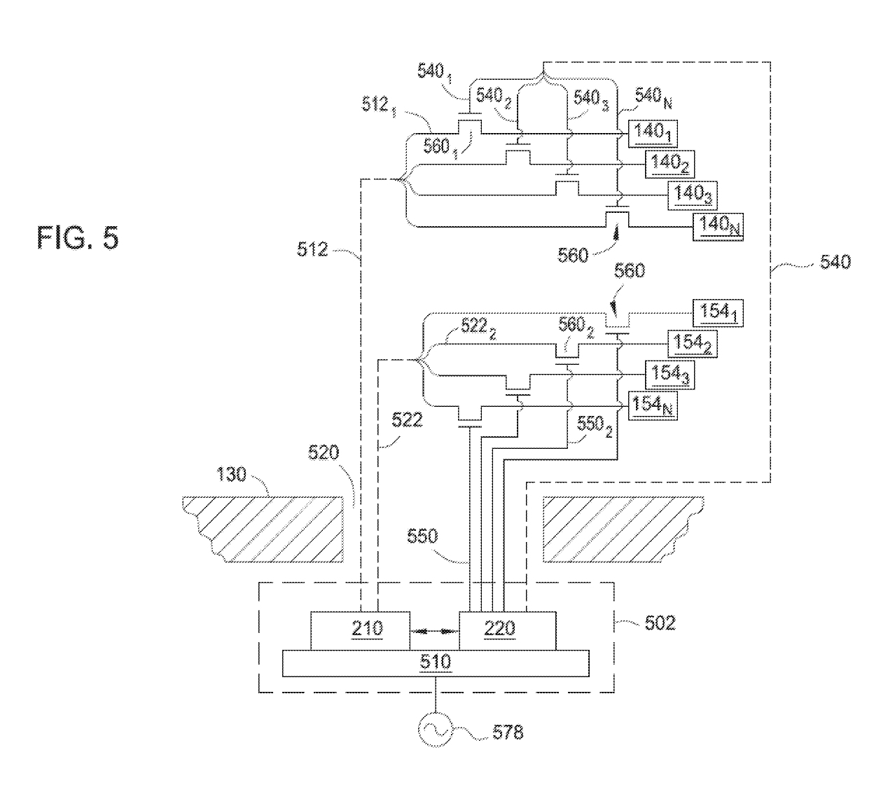

Turning to FIG. 5, a graphical depiction is provided for a wiring schema for the main resistive heaters 154 and the spatially tunable heaters 140. The wiring schema provides for individual control, as opposed to multiplex control, over the spatially tunable heaters 140. The individual control enables any one spatially tunable heater 140, or selection of spatially tunable heaters 140, to be made active at the same time as any other spatially tunable heater 140, or selection of spatially tunable heaters 140. The wiring schema allows the independent control of an output to one of the plurality of spatially tunable heaters relative to another of the plurality of spatially tunable heaters. The spatially tunable heaters 140 do not have the power cycled between an on and an off state in order to allow power to other spatially tunable heater 140, or selection of spatially tunable heaters 140. This arrangement advantageously allows a quick response time at the spatially tunable heaters 140 for achieving a tailored temperature profile.

The main resistive heaters 154 and the spatially tunable heaters 140 may be attached to a control board 502. The control board 502 may be attached to a power source 578 through a single RF filter 510. Since each heater 154, 140 shares the single RF filter 510 and does not have its own RF filter, space in the substrate support assembly 126 is conserved and additionally costs associated with the additional filters are advantageously mitigated. Control board 502 is similar to controller 202 shown in FIGS. 1 and 2, and has a similar version of the electrical controller 210 and the optical controller 220. The control board 502 may be internal or external to the substrate support assembly 126. In one embodiment the control board 502 is formed between the facility plate 180 and the cooling base 130.

The spatially tunable heaters 140₍₁₋ₙ₎ are figuratively shown, and it should be understood that spatially tunable heater 140₁ may represent a large group of spatially tunable heaters in a common zone, or alternatively, all the spatially tunable heaters 140 disposed across the substrate support assembly 126. In one implementation, there are an order of magnitude more spatially tunable heaters 140 than main heaters 154, and an order of magnitude more connections to the electrical controller 210 and the optical controller 220.

The electrical controller 210 accepts a plurality of connectors 512 from the spatially tunable heaters 140 through one or more holes or slots 520 formed through the cooling base 130. The connectors 512 may contain a number of connections suitable for communicating between the spatially tunable heaters 140 and the electrical controller 210. The connectors 512 may be a cable, individual wires, a flat flexible cable such as a ribbon, a mating connector, or other suitable technique for transmitting signals between the spatially tunable heaters 140 and the electrical controller 210. In one embodiment, the connectors 512 are ribbon cables. The connectors 512 will be discussed using the term power ribbon 512.

The power ribbon 512 may be connected at one end to the spatially tunable heaters 140 in the ESC 132 and connect at the other end to the electrical controller 210. The power ribbon 512 may connect to the electrical controller via direct wiring, a socket, or suitable receptacle. In one embodiment, the electrical controller 210 has a socket configured for a high density of connections. The power ribbons 512 may use high density connectors to provide the large number of connections, such as 50 or more connections, from the spatially tunable heaters 140 to the electrical controller 210. The electrical controller 210 may have a high density interconnect (HDI) with a wiring density per unit area greater than conventional printed circuit boards. The HDI may interface with the high density connector of the power ribbon 512. The connector advantageously allows a high density of connections and easy assembly and disassembly of the substrate support assembly 126. For example, the ESC 132 may undergo maintenance, resurfacing or replacement, and the connectors provide a quick and easy way to remove the ESC 132 for maintenance and quickly reconnect the ESC 132 back to the substrate support assembly 126.

The electrical controller 210 may additionally accept a plurality of power ribbons 522 from the main resistive heaters 154 through the slot 520 formed through the cooling base 130. The power ribbons 512, 522 graphically depict a number of power leads for each spatially tunable heater 140 and main resistive heater 154. For example, power ribbon 512 includes a plurality of separate positive and negative power leads for each spatially tunable heater 140. Likewise, power ribbon 522 comprises separate positive and negative power leads for each main resistive heater 154. In one embodiment, each power lead has a switch 560 managed by the optical controller 220. The switch 560 may reside in the electrical controller 210, on the control board 502 or other suitable location. It is contemplated that a single ribbon, or even three or more equally spaced ribbons, may be utilized to route the power leads for the spatially tunable heaters 140 and main resistive heater 154. The equally spaced ribbons enhance field uniformity and uniformity of processing results.

The optical controller 220 is connected to an external controller (148 in FIG. 1) and is configured to provide instructions to the electrical controller for powering each spatially tunable heater 140. The optical controller 220 accepts a plurality of control ribbons 540 for managing the spatially tunable heaters 140. In one embodiment, the control ribbons 540 are imbedded in the control board 502 and connect the optical controller 220 to the electrical controller 210. For example, the control ribbons 540 may be circuitry connecting the two controllers 210, 220. In another embodiment, the control ribbon may attach the optical controller 220 to the electrical controller 210 via a cable or other suitable connection external to the control board 502. In yet another embodiment, the control ribbon 540 may pass through the slot 520 formed through the cooling base and manage each spatially tunable heater 140 individually.

The optical controller 220 may optionally accept a plurality of control ribbons 550 for managing the main resistive heaters 154. Alternatively, the main resistive heaters may be managed by a second optical controller or by an external controller. Similar to the control ribbon 540, control ribbon 550 may be imbedded in the control board 502 or attached to the main resistive heaters 154. Alternately, the main resistive heaters may not have a control ribbon 550 and the cycling and intensity of the power may be managed externally at the power source 138.

The ribbons 540, 550 graphically depict a number of control leads for each spatially tunable heater 140 and main resistive heater 154. For example, control ribbon 540 comprises separate positive and negative control leads for a plurality of spatially tunable heaters 140. The optical controller 220 may take input, from a program, a temperature measuring device, an external controller, a user, or another other source. The optical power controller 220 may determine which spatially tunable heaters 140 and/or main resistive heaters 154 to manage. As the optical controller 220 uses optics to communicate with other devices that are external to the RF environment, such as the electrical controller 210, the optical power controller 220 is not subject to RF interference and does not propagate the RF signal to regions outside of the processing chamber. It is contemplated that a single ribbon, or even three or more ribbons, may be utilized to route the control leads.

The control ribbons 540 provide signals generated by the optical controller 220 to control the state of a switch 560. The switch 560 may be a field effect transistor, or other suitable electronic switch. Alternately, the switch 560 may be embedded in an optically controlled circuit board in the electrical controller 210. The switch 560 may provide simple cycling for the heaters 154, 140 between an energized (active) state and a de-energized (inactive) state.

The controller 202 may control at least one or more of the duty cycle, voltage, current, or duration of power applied to one or more selected spatially tunable heaters 140 relative another and at the same time. In one embodiment, the controller 202 provides a signal along the control ribbon 540₁ to instruct the switch 560₁ to allow 90% of the power to pass therethrough. The electrical controller 210 provides about 10 watts of power along the power ribbon 512₁. The switch 560₁ allows 90% of the supplied power to pass through to a spatially tunable heater 140₁ which heats up with about 9 watts of power.

In another embodiment, the controller 202 provides a signal along the control ribbon 550₂ to instruct the switch 560₂ to allow 100 percent of the power to pass therethrough. The electrical controller 210 provides about 100 Watts of power along the power ribbon 522₂. The switch 560₂ allows 100 percent of the supplied power to pass through to the main resistive heater 154₂ which heats up with about 100 Watts of power. Similarly, the main resistive heaters 154_{(1-N)} may all be operated from controller 202.

In yet another embodiment, the tuning heater controller 202 provides a signal along the control ribbon 540 to instruct the switches 560 to be in either an active state that allows power to pass therethrough or an inactive state that prevents power from passing therethrough. The electrical controller 210 provides about 10 Watts of power along the power ribbon 512 to each individual spatially tunable heater 140 coupled to a switch 560 in the active state. The tuning heater controller 202 independently controls at least one of the duration that the switch 560 remains in the active state and the duty cycle of each switch 560 relative to the other switches 560, which ultimately controls the temperature uniformity of the substrate support assembly 126 and substrate positioned thereon. The switches 560 controlling power to the main resistive heaters 154 may be similarly controlled.

In another embodiment, each main resistive heater 154_{(1-N)}, representing a separate zone, may have a separate controller 202. In this embodiment, the spatially tunable heaters_{(1-N)} common to a zone with one main resistive heater 154_{(1-N)} may share the controller 202 with the common main resistive heater 154_{(1-N)}. For example, if there were four zones, there would be four main resistive heaters 154₍₁₋₄₎ and four equally spaced controllers 202.

In other embodiments, separate controllers 202 may be utilized to split up the number of spatially tunable heaters 140 serviced by a single controller. For instance, each control ribbon 540 may have a separate optical controller 220 for managing a set number of spatially tunable heaters 140 individual. Splitting up the control of the spatially tunable heaters 140 allows for smaller controllers and less space for routing the ribbons through the slots 520 formed through the cooling base.

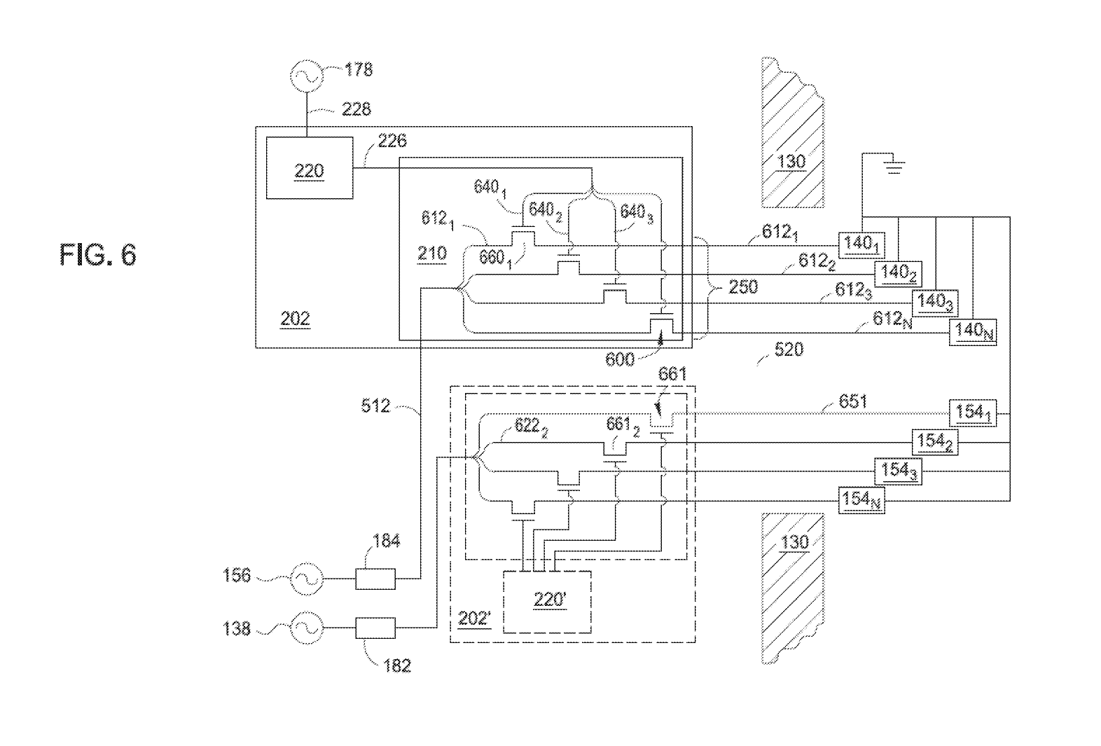

Turning to FIG. 6, a graphical depiction is provided for another wiring schema for the main resistive heaters 154 and the spatially tunable heaters 140. The wiring schema depicted in FIG. 6 provides for individual control of the spatially tunable heaters 140. The spatially tunable heaters 140 are attached to the tuning heater controller 202. The electrical controller 210 on the control board 502 is attached to the power source 156 through the RF filter 184. The optical controller 220 is connected to an external controller (148 in FIG. 1) and is configured to provide instructions to the electrical controller for powering each spatially tunable heater 140. The optical controller 220 communicates through the fiber optic interface 226 with the electrical controller 210 to manage the spatially tunable heaters 140. Similar to the wiring schema of FIG. 5, the wiring schema of FIG. 6 provides for independent control of an output of one of the plurality of spatially tunable heaters relative to the other spatially tunable heaters.

The main resistive heaters 154 may optionally be attached to a tuning heater controller 202′, the tuning heater controller 202, or other controller external from the substrate support assembly 126. The tuning heater controller 202′ may be substantially similar to the tuning heater controller 202. It should be appreciated that the control of the main resistive heaters 154 may be similar to that described for the spatially tunable heaters 140. Alternately, the main resistive heaters 154 may be managed externally as shown in FIG. 1.

The spatially tunable heaters 140₍₁₋ₙ₎ are figuratively shown and should be understood that spatially tunable heater 140₁ may represent a large group of spatially tunable heaters in a common zone, or alternatively, to all the spatially tunable heaters 140 disposed across the substrate support assembly 126. Each spatially tunable heater 140 has a connector 250 for transmitting power to the spatially tunable heater 140 from the electrical controller 210.

The electrical controller 210 accepts a plurality of power ribbons 612 from the spatially tunable heaters 140 through one or more holes or slots 520 formed through the cooling base 130. The ribbons 612 graphically depict a number of power leads for each spatially tunable heater 140. The power ribbon 612 provides an electrical pathway for power to the spatially tunable heaters 140. In one embodiment, the power ribbon 612 comprises separate positive power leads for each spatially tunable heater 140. The power ribbon 612 may optionally have a single negative power lead common to all the spatially tunable heaters 140 attached to the power ribbon 612. Alternately, the power ribbon 612 may have no negative power return path and the return path for the electrical current may be provided through a separate cable, a common bus, or other suitable connector. In another embodiment, the power ribbon 612 comprises separate negative power leads for each spatially tunable heater 140. The power ribbon 612 may optionally have a single positive power lead common to all the spatially tunable heaters 140 attached to the power ribbon 612. Alternately, the power ribbon 612 may have no positive power supply path and the power supply path for the electrical current may be provided through a separate cable, a common bus, or other suitable connector.

The electrical controller 210 may have a plurality of switches 660 formed therein. Each switch 660 may accept a positive power lead from one of the power ribbons 612 to control individual spatially tunable heaters 140. The optical controller 220 manages the switches 660 via a fiber optic interface 226 to the electrical controller 210. Circuitry 640 may be imbedded in the electrical controller 210 or the tuning heater controller 202 to convert the optical signal to an electrical signal for provided instructions to the switches 660.

The switches 660 may be a field effect transistor, or other suitable electronic switch. The switch 660 may provide simple cycling for the heaters 154, 140 between an energized (active) state and a de-energized (inactive) state. Alternately, the switch 660 may be another suitable device, which can control the amount of power supplied to the spatially tunable heaters 140.

The switches 660 may be formed internal to the substrate support assembly 126, such as in the electrostatic chuck 132, the cooling base 130, heater assembly 170 and the facility plate 180. Alternately, the switched 660 may be formed external to the substrate support assembly 126 or even the processing chamber 100, such as in the controller 148.

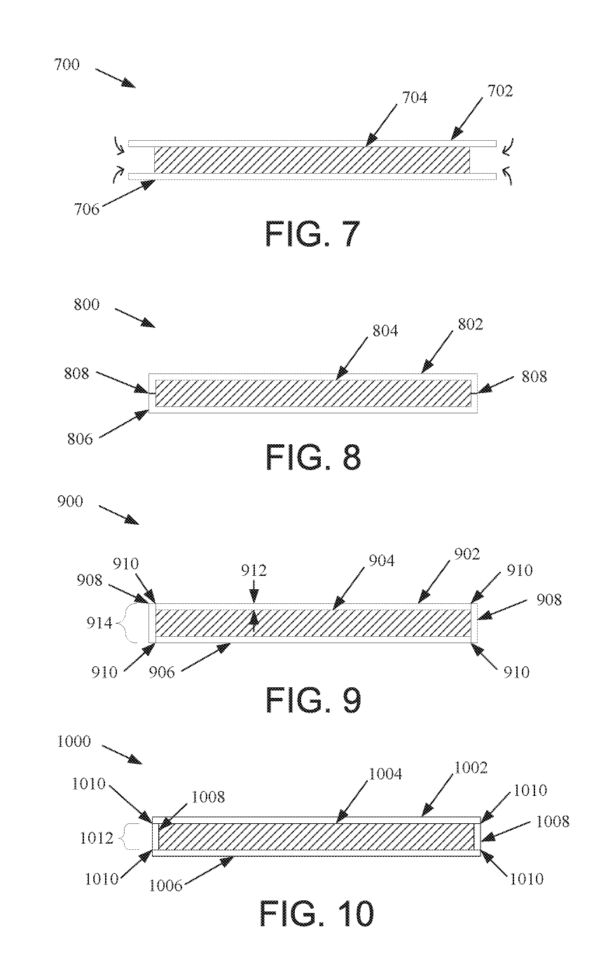

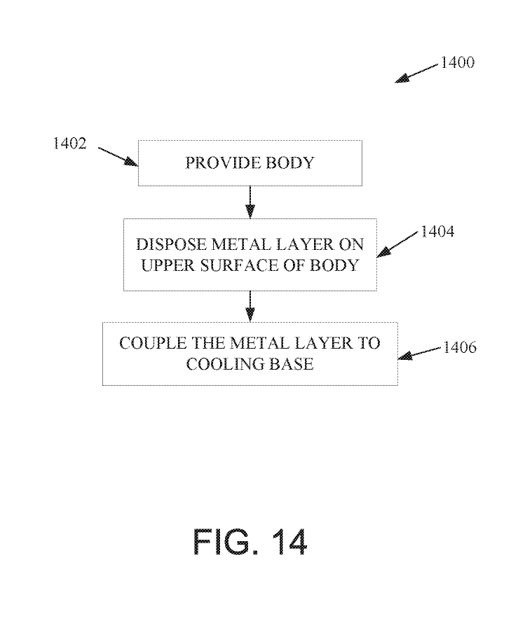

FIGS. 7-10 and 12 illustrate various configurations of a heater assembly that is encased in a metal layer. FIG. 7 is an illustration 700 showing a process of disposing metal layers 702 and 706 onto a body 704 of a heater assembly. The metal layers 702 and 706 may correspond to the metal layers 143 and 141 of FIG. 2, respectively. The body 704 may correspond to the body 152 of FIG. 2. Although the sidewall of the body 704 may be shown as vertical, in embodiments the sidewall of the body 704 may be curved, as illustrated in FIG. 14, or may have other shapes. The metal layers 702 and 706 may have a larger diameter than the body 704, resulting in portions of metal layers 702 and 706 extending beyond the sidewall of body 704. The metal layer 702 may be disposed onto the top surface of the body 704. Additionally, the metal layer 706 may be disposed on the bottom surface of the body 704. In one embodiment, the metal layers 702 and 706 may be disposed on the body 704 by a lamination process. The lamination process includes subjecting the metal layers 702 and 706 and the body 704 to heat and pressure, forming a bond between the surfaces of the body 704 and metal layers 702 and 706. In another embodiment, the metal layers 702 and 706 may be disposed on the body 704 using a bonding agent to adhere the metal layers 702 and 706 to the body 704. Once the metal layers 702 and 706 have been disposed on the body 704, the portions of metal layers 702 and 706 extending beyond the sidewall of the body 704 may be folded as illustrated in FIG. 7 and crimped (e.g., folded or compressed) together.

FIG. 8 is an illustration of a heater assembly 800 according to one embodiment. The heater assembly 800 includes a body 804, a metal layer 802 and a metal layer 806. The heater assembly 800, metal layers 802 and 806 and the body 804 may correspond to the heater assembly 170, metal layers 143 and 141 and body 152 of FIG. 2, respectively. The metal layers 802 and 806 may be disposed on the top (upper) and bottom (lower) surfaces of the body 804 and crimped together using the process previously described in FIG. 7. A welding process may then be performed to bond the metal layers together. A continuous weld 808 may couple metal layers 802 and 806 to enclose the body 804. The weld may be performed using any process capable of producing a continuous weld, such as an EB weld, TIG weld, or another suitable process. This results in a heater assembly 800 having a body that is shielded from RF signals and etching chemicals.

FIG. 9 is an illustration of a heater assembly 900 according to another embodiment. The heater assembly 900 includes a body 904, a metal layer 902, a metal layer 906 and a metal ring 908. The heater assembly 900, metal layers 902 and 906 and the body 904 may correspond to the heater assembly 170, metal layers 143 and 141 and body 152 of FIG. 2, respectively. The metal layers 902 and 906 may be disposed onto the surfaces of body 904 using the process previously described in FIG. 7 and have a thickness 912. In one embodiment, the thickness 912 may be between 0.001″ and 0.125″ In the present embodiment, metal layers 902 and 906 may not have portions that extend beyond the sidewall of the body 904, or that extend only minimally beyond the sidewall of the body 904. For example, a diameter of the metal layers 902, 906 may be approximately equal to a diameter of the body 904. The metal ring 908 may be located on the sidewall of the body 904. The metal ring 908 may be formed from Al, Ag, Cu, Au, Zn, stainless steel, an alloy of any of these metals, or another suitable material. The metal ring 908 may have a thickness 914 between 0.001″ to 0.25″. In one embodiment, the metal ring 908 has a thickness of about 0.125-0.25″.The metal ring 908 may be coupled to metal layers 902 and 906 by continuous welds 910 on the top surface of metal layer 902 and the bottom surface of metal layer 906 to enclose the body 904. The weld may be performed using any process capable of producing a continuous weld, such as an EB weld, TIG weld, or another suitable process.

FIG. 10 is an illustration of a heater assembly 1000 according to a further embodiment. The heater assembly 1000 includes a body 1004, a metal layer 1002, a metal layer 1006 and a metal ring 1008. The heater assembly 1000, metal layers 1002 and 1006 and the body 1004 may correspond to the heater assembly 170, metal layers 143 and 141 and body 152 of FIG. 2, respectively. The metal layers 1002 and 1006 may be disposed onto the surfaces of body 1004 using the process previously described in FIG. 7. In the present embodiment, metal layers 1002 and 1006 have portions that extend beyond the sidewall of the body 1004. Metal ring 1008 may be located on the sidewall of the body 1004. The metal ring 1008 may be formed from Al, Ag, Cu, Au, Zn, stainless steel, an alloy of any of these metals, or another suitable material. The metal ring 1008 may have a thickness 1012 between 0.001″ to 0.25″. The metal ring 1008 may be coupled to metal layers 1002 and 1006 by continuous welds 1010 on the sides of metal layers 1002 and 1006 to enclose the body 1004. The weld may be performed using any process capable of producing a continuous weld, such as an EB weld, TIG weld, or another suitable process.

FIG. 11 is an illustration of a metal layer 1100 according to an embodiment. The metal layer 1100 may correspond to the metal layers 141 and 143 of FIG. 2. The metal layer 1100 includes a portion near an outside diameter 1102 and a portion near a center 1104. The portion near the outside diameter 1102 may have a thickness that is greater than the portion near the center 1104 in order to provide more material at the outside diameter to perform the welding processes as previously described. The portion near the outside diameter may extend from the outside diameter to approximately the diameter of the body of the heater assembly in one embodiment. The portion near the center may extend from approximately the diameter of the body of the heater assembly to the center of the metal layer 1100 in one embodiment. The portion near the outside diameter 1102 may have a thickness between 0.001″ and 0.125″. The portion near the center 1104 may have a thickness between 0.001″ and 0.125″. Accordingly, the metal layer 1100 may have a ring about the outer perimeter that is thicker than a remainder of the metal layer 1100.

FIG. 12 is an illustration of a heater assembly 1200 according to another embodiment. The heater assembly 1200 includes a body 1204, a metal layer 1202, and a metal layer 1206. The heater assembly 1200, metal layers 1202 and 1206 and the body 1204 may correspond to the heater assembly 170, metal layers 143 and 141 and body 152 of FIG. 2, respectively. In the present embodiment, the sidewall of the body 1204 may be curved. The metal layers 1202 and 1206 may be disposed and crimped together using the process previously described in FIG. 7. Due to the curved sidewall of body 1204, the crimping of metal layers 1202 and 1206 may result in a curved or conical shape around the perimeter of the body 1204. A continuous weld 1208 may couple metal layers 1202 and 1206 to enclose the body 1204. The weld may be performed using any process capable of producing a continuous weld, such as an EB weld, TIG weld, or another suitable process. This results in a heater assembly 1200 having a body that is shielded from RF signals as well as etching chemicals in the processing chamber.

FIG. 13 is a flow diagram 1300 of one embodiment of a method for processing a heater assembly. At block 1302, a body may be provided for the heater assembly. The body of block 1302 may correspond to the body 152 of FIG. 2. In one embodiment, the body may be a flexible body formed of polyimide. The body may include spatially tunable heaters, main resistive heaters and temperature sensors. In one embodiment, the thickness of the body may be between 0.003″ and 0.020″. At block 1304, a first metal layer may be disposed on the upper surface of the body. The first metal layer may correspond to the metal layer 143 of FIG. 2. In one embodiment, the first metal layer may be disposed on the upper surface of the body through a lamination process. In another embodiment, the first metal layer may be disposed on the upper surface of the body using a bonding agent to adhere the metal layer to the upper surface of the body. At block 1306, a second metal layer may be disposed on the lower surface of the body. The second metal layer may correspond to the metal layer 141 of FIG. 2. The second metal layer may be disposed on the lower surface of the body using similar processes to those disclosed at block 1304. In one embodiment, the first metal layer and the second metal layer are bonded to the body in a single process. For example, the first metal layer may be disposed on the upper surface, the second metal layer may be disposed on the lower surface, and a lamination process may then be performed. In one embodiment, the lamination process causes the two metal layers to crimp around the outer side wall of the body and to come in contact.

At block 1308, the first metal layer and second metal layer may be coupled to enclose the body and form a continuous electrically conductive path around the body. In one embodiment, the first metal layer may be coupled to the second metal layer by a welding process, such as EB welding, TIG welding, or another suitable process as described in FIGS. 7 and 8. In another embodiment, the first metal layer and the second metal layer may be coupled by welding the first metal layer and the second metal layer to a metal ring as described in FIGS. 9 and 10.

FIG. 14 is a flow diagram 1400 of another embodiment of a method for processing a heater assembly. At block 1402, a body may be provided for the heater assembly. The body of block 1402 may correspond to the body 152 of FIG. 2. In one embodiment, the body may be a flexible body formed of polyimide. The body may include spatially tunable heaters, main resistive heaters and temperature sensors. At block 1404, a metal layer may be disposed on the upper surface of the body. The metal layer may correspond to the metal layer 143 of FIG. 2. In one embodiment, the first metal layer may be disposed on the upper surface of the body through a lamination process. In another embodiment, the first metal layer may be disposed on the upper surface of the body using a bonding agent to adhere the metal layer to the upper surface of the body. At block 1406, the metal layer may be coupled to a cooling base to enclose the body and form a continuous electrically conductive path around the body. The metal layer may have a larger diameter than the body, and may extend along an outer sidewall of the body to the metal cooling plate (also referred to as a cooling base). The cooling base of block 1406 may correspond to the cooling base 130 of FIG. 2. In one embodiment, the metal layer may be coupled to the cooling base by a welding process, such as EB welding, TIG welding, or another suitable process as described in FIGS. 7 and 8. In another embodiment, the metal layer and the cooling base may be coupled by welding the metal layer and the cooling base to a metal ring using a process similar to those described in FIGS. 9 and 10. The metal layer and metal cooling plate together enclose the heater assembly and form a continuous electrically conductive path around the outer sidewall of the heater assembly. In another embodiment, the body may be disposed on the cooling base, and then the metal layer may be disposed on the body and coupled to the cooling base.

While the foregoing is directed to implementations of the present invention, other and further implementations may be devised without departing from the basic scope thereof, and the scope thereof is determined by the claims that follow.

We claim:

1. A heater assembly for a substrate support assembly, comprising:
a flexible body;
one or more resistive heating elements disposed in the flexible body;
a first metal layer disposed on a top surface of the flexible body and extending at least partially onto an outer sidewall of the flexible body; and
a second metal layer disposed on a bottom surface of the flexible body and extending at least partially onto the outer sidewall of the flexible body, wherein the second metal layer is coupled to the first metal layer at the outer sidewall of the flexible body such that the first metal layer and the second metal layer enclose, and form a continuous electrically conductive path around, the outer sidewall of the flexible body.

2. The heater assembly of claim 1, wherein the flexible body comprises polyimide.

3. The heater assembly of claim 1, wherein the first metal layer and the second metal layer comprise aluminum.

4. The heater assembly of claim 1, wherein the first metal layer is coupled to the second metal layer by a weld.

5. The heater assembly of claim 1, further comprising:
a metal ring that encircles the flexible body, wherein the first metal layer and the second metal layer are coupled via respective welds to the metal ring.

6. The heater assembly of claim 1, wherein a diameter of the first metal layer and a diameter of the second metal layer are greater than a diameter of the flexible body.

7. The heater assembly of claim 1, wherein a first portion of the first metal layer and a first portion of the second metal layer have a first thickness near a center of the first metal layer and the second metal layer and a second portion of the first metal layer and a second portion of the second metal layer have a second thickness near an outer perimeter of the first metal layer and the second metal layer that is greater than the first thickness.

8. The heater assembly of claim 1, wherein the heater assembly is a component of a substrate support assembly comprising the heater assembly, a metal cooling plate coupled to a bottom surface of the heater assembly and an electrostatic chuck coupled to an upper surface of the heater assembly.

9. A substrate support assembly comprising:
a metal cooling plate;
a heater assembly coupled to the metal cooling plate, the heater assembly comprising:
a body comprising an upper surface, a lower surface and an outer sidewall, wherein the lower surface of the body is disposed on the metal cooling plate;
one or more resistive heating elements disposed in the body; and
a metal layer disposed on the upper surface of the body, wherein the metal layer extends along the outer sidewall of the body to the metal cooling plate and is coupled to the metal cooling plate, and wherein the metal layer and metal cooling plate together enclose the heater assembly and form a continuous electrically conductive path around the outer sidewall of the heater assembly; and
an electrostatic chuck disposed on the heater assembly, the electrostatic chuck comprising a ceramic body and an electrode disposed in the ceramic body.

10. The substrate support assembly of claim 9, wherein the metal layer comprises a first portion disposed on the upper surface of the body and a second portion that extends along the outer sidewall, wherein the second portion of the metal layer comprises a metal ring that encircles the heater assembly, and wherein the first portion of the metal layer and the metal cooling plate are each welded to the metal ring.

11. The substrate support assembly of claim 9, wherein the metal cooling plate and the metal layer comprise aluminum.

12. The substrate support assembly of claim 9, wherein the body is a flexible body that comprises polyimide.

13. The substrate support assembly of claim 9, wherein a first portion of the metal layer has a first thickness near a center of the metal layer and a second portion of the metal layer has a second thickness near an outer perimeter of the metal layer that is greater than the first thickness.

14. The substrate support assembly of claim 9, wherein an upper surface of the cooling plate comprises a recessed portion, and wherein the heater assembly is disposed in the recessed portion of the cooling plate.

15. The substrate support assembly of claim 9, wherein a diameter of the metal layer is greater than a diameter of the body.

16. The substrate support assembly of claim 9, further comprising a radio frequency (RF) signal generator coupled to the cooling plate, wherein an RF signal to be generated by the RF signal generator is to travel along the continuous electrically conductive path without entering the heater assembly.

17. A method comprising:
providing a heater assembly comprising a body having an upper surface, a lower surface and an outer sidewall, wherein the heater assembly further comprises and a plurality of heating elements disposed in the flexible body;
disposing a first metal layer on the upper surface of the heater assembly, wherein the first metal layer extends at least partially onto an outer sidewall of the body;
disposing a second metal layer on the lower surface of the heater assembly, wherein the second metal layer extends at least partially onto the outer sidewall of the body; and
coupling the first metal layer and the second metal layer such that the first metal layer and second metal layer enclose, and form a continuous electrically conductive path around, the outer sidewall of the body.

18. The method of claim 17, wherein disposing the first metal layer on the upper surface of the body comprises laminating the first metal layer on the upper surface of the body and disposing the second metal layer on the lower surface of the body comprises laminating the second metal layer on the bottom surface of the body, wherein the laminating of the first metal layer and the second metal layer is performed by applying heat and pressure.

19. The method of claim 17, wherein coupling the first metal layer and the second metal layer comprises welding the first metal layer to the second metal layer.

20. The method of claim 17, wherein coupling the first metal layer and the second metal layer comprises:
disposing a metal ring around the body, wherein the metal ring is disposed between the first metal layer and the second metal layer; and
welding the metal ring to the first metal layer and the second metal layer.
